(19) United States
(12) Patent Application Publication
(10) Pub. No.: US 2009/0095184 A1
(43) Pub. Date: Apr. 16, 2009

(54) NEGATIVE WORKING, HEAT-SENSITIVE LITHOGRAPHIC PRINTING PLATE PRECURSOR

(75) Inventors: Joan Vermeersch, Deinze (BE); Dirk Kokkelenberg, St. Niklaas (BE); Hubertus Van Aert, Pulderbos (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS NV, Mortsel (BE)

(21) Appl. No.: 12/282,902

(22) PCT Filed: Feb. 21, 2007
(86) PCT No.: PCT/EP2007/051655

§ 371 Date: Sep. 15, 2008

Related U.S. Application Data
(60) Provisional application No. 60/784,417, filed on Mar. 21, 2006.

(30) Foreign Application Priority Data
Mar. 17, 2006 (EP) 06111322.1

(51) Int. Cl. B41F 1/18; G03F 7/004; B41M 5/00; G03F 7/20

(52) U.S. Cl. 101/463.1; 430/270.1; 430/302; 101/450.1

(57) ABSTRACT

A heat-sensitive negative-working lithographic printing plate precursor includes a support having a hydrophilic surface or which is provided with a hydrophilic layer and a coating provided thereon, the coating including an image-recording layer which includes hydrophobic thermoplastic polymer particles wherein the hydrophobic thermoplastic polymer particles include a polyester and have an average particle diameter from 18 nm to 50 nm.

### CROSS-REFERENCE TO RELATED APPLICATIONS

This application is a 371 National Stage Application of PCT/EP2007/051655, filed Feb. 21, 2007. This application claims the benefit of U.S. Provisional Application No. 60/784,417, filed Mar. 21, 2006, which is incorporated by reference herein in its entirety. In addition, this application claims the benefit of European Application No. 06111322.1, filed Mar. 17, 2006, which is also incorporated by reference herein in its entirety.

### BACKGROUND OF THE INVENTION

1. Field of the Invention

The present invention relates to a heat-sensitive, negative-working lithographic printing plate precursor.

2. Description of the Related Art

Lithographic printing presses use a so-called printing master such as a printing plate which is mounted on a cylinder of the printing press. The master carries a lithographic image on its surface and a print is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e., ink-accepting, water-repelling) areas as well as hydrophilic (or oleophobic, i.e., water-accepting, ink-repelling) areas. In so-called driographic printing, the lithographic image consists of ink-accepting and ink-adhesive (ink-repelling) areas and during driographic printing, only ink is supplied to the master.

Printing masters are generally obtained by the image-wise exposure and processing of an imaging material called a plate precursor. In addition to the well-known photosensitive, so-called pre-sensitized plates, which are suitable for UV contact exposure through a film mask, heat-sensitive printing plate precursors have also become very popular in the late 1990s. Such thermal materials offer the advantage of daylight stability and are especially used in the so-called computer-to-plate method wherein the plate precursor is directly exposed, i.e., without the use of a film mask. The material is exposed to heat or to infrared light and the generated heat triggers a (physico-)chemical process, such as ablation, polymerization, insolubilization by crosslinking of a polymer, heat-induced solubilization, or particle coagulation of a thermoplastic polymer latex.

The most popular thermal plates form an image by a heat-induced solubility difference in an alkaline developer between exposed and non-exposed areas of the coating. The coating typically includes an oleophilic binder, e.g., a phenolic resin, of which the rate of dissolution in the developer is either reduced (negative working) or increased (positive working), by the image-wise exposure. During processing, the solubility differential leads to the removal of the non-image (non-printing) areas of the coating, thereby revealing the hydrophilic support, while the image (printing) areas of the coating remain on the support. Typical examples of such plates are described in, e.g., EP-A 625728, EP-A 823327, EP-A 825927, EP-A 864420, EP-A 894622 and EP-A 901902. Negative working embodiments of such thermal materials often require a pre-heat step between exposure and development as described in, e.g., EP-A 625,728.

Negative working plate precursors which do not require a pre-heat step may contain an image-recording layer that works by heat-induced particle coalescence of a thermoplastic polymer latex, as described in, e.g., EP-A 770 494, EP-A 770 495, EP-A 770 496 and EP-A 770 497. These patents disclose a method for making a lithographic printing plate including the steps of (1) image-wise exposing an imaging element including hydrophobic thermoplastic polymer particles dispersed in a hydrophilic binder and a compound capable of converting light into heat, and (2) developing the image-wise exposed element by applying fountain solution and/or ink.

EP-A 1 342 568 describes a method of making a lithographic printing plate including the steps of (1) image-wise exposing an imaging element including hydrophobic thermoplastic polymer particles dispersed in a hydrophilic binder and a compound capable of converting light into heat, and (2) developing the image-wise exposed element by applying a gum solution, thereby removing non-exposed areas of the coating from the support.

WO 2006/037716 describes a method for preparing a lithographic printing plate which includes the steps of (1) image-wise exposing an imaging element including hydrophobic thermoplastic polymer particles dispersed in a hydrophilic binder and a compound capable of converting light into heat, and (2) developing the image-wise exposed element by applying a gum solution, thereby removing non-exposed areas of the coating from the support and characterized by an average particle size of the thermoplastic polymer particles between 40 nm and 63 nm and wherein the amount of the hydrophobic thermoplastic polymer particles is more than 70% and less than 85% by weight, relative to the image recording layer.

EP-A 1 614 538 describes a negative working lithographic printing plate precursor which includes a support having a hydrophilic surface or which is provided with a hydrophilic layer and a coating provided thereon, the coating including an image-recording layer which includes hydrophobic thermoplastic polymer particles and a hydrophilic binder, characterized in that the hydrophobic thermoplastic polymer particles have an average particle size in the range from 45 nm to 63 nm, and that the amount of the hydrophobic thermoplastic polymer particles in the image-recording layer is at least 70% by weight relative to the image-recording layer.

EP-A 1 614 539 and EP-A 1 614 540 describe a method of making a lithographic printing plate including the steps of (1) image-wise exposing an imaging element disclosed in EP-A 1 614 538, and (2) developing the image-wise exposed element by applying an aqueous, alkaline solution.

EP-A 1 564 020 describes a printing plate including a hydrophilic support and provided thereon, an image formation layer containing thermoplastic resin particles in an amount from 60% to 100% by weight, the thermoplastic particles having a glass transition point (Tg) and an average particle size of from 0.01 to 2 μm, more preferably from 0.1 to 2 μm. As thermoplastic particles, polyester resins are preferred. EP 1 564 020 discloses printing plate precursors including polyester thermoplastic particles, of which the particle size is 160 nm.

A problem associated with negative-working printing plates that work according to the mechanism of heat-induced latex-coalescence is the complete removal of the non-exposed areas during the development step (i.e., clean-out). An insufficient clean-out may result in toning on the press, i.e., an undesirable increased tendency of ink-acceptance in the non-image areas. This clean-out problem tends to become worse when the particle size of the thermoplastic particles, used in the printing plate, decreases, as mentioned in EP-A 1 614 538, EP-A 1 614 539, EP-A 1 614 540 and EP-A 1 145 848. A decrease of the particle diameter of the hydrophobic thermoplastic particles in the imaging layer may however further increase the sensitivity of the printing plate precursor and improve the obtained resolution on the prints.

### SUMMARY OF THE INVENTION

In order to overcome the problems described above, preferred embodiments of the present invention provide a negative working, heat-sensitive lithographic printing plate precursor which has excellent printing properties with reduced or without toning and a high sensitivity.

This is achieved by a heat-sensitive negative-working lithographic printing plate precursor including a support having a hydrophilic surface or which is provided with a hydrophilic layer and a coating provided thereon, the coating including an image-recording layer which includes hydrophobic thermoplastic polymer particles wherein the hydrophobic thermoplastic polymer particles include a polyester and have an average particle diameter from 18 to 50 nm.

It was surprisingly discovered that a negative-working lithographic printing plate precursor including hydrophobic thermoplastic particles with an average particle diameter from 18 to 50 nm provides a printing plate with excellent clean-out properties when the hydrophobic thermoplastic particles include a polyester. Furthermore, the printing plate of the preferred embodiments of the present invention provide prints with an excellent image quality.

Other features, elements, steps, characteristics and advantages of the present invention will become more apparent from the following detailed description of preferred embodiments of the present invention.

### DETAILED DESCRIPTION OF PREFERRED EMBODIMENTS

The coating of the printing plate precursor according to the preferred embodiments of the present invention includes hydrophobic thermoplastic particles. The coating may include one or more layer(s). The layer including the hydrophobic thermoplastic particles is referred to herein as an image-recording layer.

The hydrophobic particles of the preferred embodiments of the present invention have an average particle diameter from 18 to 50 nm, preferably from 18 to 40 nm and more preferably from 18 to 30 nm. Average particle diameter is meant to be the number average particle size throughout the entire description and the claims of this application.

The particle diameter is defined herein as the particle diameter, measured by Photon Correlation Spectrometry, also known as Quasi-Elastic or Dynamic Light-Scattering. This technique produces values of the particle diameter that match well with the particle diameter measured with transmission electronic microscopy (TEM) as disclosed by Stanley D. Duke et al., in “Calibration of Spherical Particles by Light Scattering”, in Technical Note-002B, May 15, 2000 (revised from a paper published in Particulate Science and Technology 7, pp. 223-228 (1989)). In the examples, the particle diameter is measured with a Brookhaven BI-90 analyzer, commercially available from Brookhaven Instrument Company, Holtsville, N.Y., USA.

The amount of hydrophobic thermoplastic polymer particles contained in the coating may be between 20 and 90 percent by weight relative to the weight of all the components in the coating. In a preferred embodiment, the amount of hydrophobic thermoplastic polymer particles present in the coating is between 40 and 85 percent, more preferably between 50 and 80, and most preferably between 60 and 75 percent by weight relative to the weight of all the components in the coating.

The thermoplastic hydrophobic particles of the preferred embodiments of the present invention include a polyester. Besides a polyester, the thermoplastic hydrophobic particles may include different polymers; e.g., polyethylene, poly(vinyl)chloride, polymethyl(meth)acrylate, polyethyl (meth)acrylate, polyvinylidene chloride, poly(meth)acrylonitrile, polyvinylcarbazole, polystyrene, polyurethanes or copolymers thereof. Besides a polyester, the hydrophobic thermoplastic particles include preferably a co-polymer, as disclosed in EP 1 219 416, including at least 5 percent by weight of nitrogen containing units. The ratio between the polyester and the other polymers or co-polymers is preferably between 9:1 and 1:9, more preferably between 6:4 and 4:6. In an alternative preferred embodiment, the hydrophobic thermoplastic particles consist essentially of a polyester. The image-recording layer may include different hydrophobic thermoplastic particles including different polymers or copolymers. Preferably, the coating may include hydrophobic thermoplastic particles consisting essentially of a polyester and hydrophobic thermoplastic particles including another polymer or co-polymer; e.g., polyethylene, poly(vinyl)chloride, polymethyl (meth)acrylate, polyethyl(meth)acrylate, polyvinylidene chloride, poly(meth)-acrylonitrile, polyvinylcarbazole, polystyrene, polyurethanes or copolymers thereof. In a preferred embodiment, the image recording layer may include hydrophobic thermoplastic particles consisting essentially of a polyester and hydrophobic thermoplastic particles, as disclosed in EP 1 219 416, including a co-polymer including at least 5 percent by weight of nitrogen containing units. The ratio between hydrophobic thermoplastic particles, consisting essentially of a polyester, and hydrophobic thermoplastic particles, including a copolymer including at least 5 percent by weight of nitrogen containing units, is preferably between 9:1 and 1:9, more preferably between 6:4 and 4:6. In an alternative preferred embodiment, the image recording layer includes hydrophobic thermoplastic particles consisting essentially of a polyester.

A polyester polymer is a polymer including —CO—O— recurring groups in the main chain of the polymer. The polyester polymers according to the preferred embodiments of the present invention are preferably prepared by a poly-condensation polymerization reaction, well known in the art, as described for example in the handbook Organic Polymer Chemistry, pages 203 to 244, of K. J. Saunders, first published in 1973 by Chapman and Hall Ltd. A polyester is obtained by esterification of polybasic organic acids (monomers with 2 or more carboxyl groups) with polyhydric alcohols (monomers with 2 or more hydroxyl groups).

Linear polyester polymers are obtained by reaction of one or more types of a diol (monomer containing two hydroxyl group) with one or more types of a dibasic acid (monomer containing two carboxyl group) or an ester thereof. The highest Molecular Weight of the linear polyesters are obtained when the molar ratio of the hydroxyl containing monomers to the carboxyl containing monomers is approximately 1. An excess of hydroxyl containing monomers up to 70 to 100% may be used in the reaction mixture, which excess is distilled off during esterification and poly-condensation. Often, ester derivatives (e.g., methyl ester) of the carboxyl containing monomers are used in the poly-condensation reaction.

The poly-condensation proceeds advantageously in the melt of the reactants in the presence of a catalyst used for that reaction, e.g., zinc acetate and antimony(III) oxide, as described for example in U.S. Pat. No. 3,054,703.

The polyester according to the preferred embodiments of the present invention preferably includes aryl or heteroaryl dicarboxylic acid moieties as predominant dicarboxylic acid. Preferably, the aryl or heteroaryl dicarboxylic acid moieties are present for at least 80 mole percent with respect to the total acid moiety content of the polyester. More preferably, phenyl or naphthyl dicarboxylic acid moieties are the predominant acid moieties, preferably for at least 80 mole percent with respect to the total acid moiety content of the polyester. The polyester according to the preferred embodiments of the present invention preferably includes alkylene diol moieties as predominant diol moieties. Examples of aromatic dicarboxylic acid moieties are moieties of terephthalic acid, isophthalic acid, naphthalene di-carboxylic acids, 4,4′diphenylene dicarboxylic acid, 4,4′diphenylether dicarboxylic acid, 4,4′diphenylmethane di-carboxylic acids, 4,4′dimethylsulpho-dicarboxylic acid. Examples of alkylene diol moieties are moieties of ethylene glycol, diethylene glycol, 1,3-propanediol, 1,4-butanediol, 2-methyl-1,5-pentanediol, neopentylglycol, 1,4-cyclohexanedimethanol, p-xylene glycol.

Preferably, isophthalic and naphthalenedicarboxylic acid moieties are the predominant dicarboxylic acid moieties in the polyester and are present for at least 80 mole percent with respect to the total acid moiety content of the polyester. Preferably, the naphthalenedicarboxylic acid moiety is present for at least 25%, more preferably for at least 40% with respect to the total acid moiety content of the polyester.

It has been observed that incorporation of aryl or heteroaryl, preferably phenyl or napthyl, dicarboxylic acid moieties in the amounts mentioned above increases the Tg and the solvent resistance of the obtained polyester. The latter may result in an increased run length of a printing plate obtained from a printing plate precursor including hydrophobic thermoplastic particles including a polyester according to the preferred embodiments of the present invention. Preferably, the Tg of the polyesters according to the preferred embodiments of the present invention are above 50° C., more preferably above 60° C., most preferably above 65° C. Preferably the Tg is below 180° C., more preferably below 130° C. and most preferably below 110° C.

The hydrophobic thermoplastic polymer particles present in the image-recording layer are preferably applied onto the lithographic support in the form of a dispersion in an aqueous coating liquid. These dispersions can be made by adding the polymer to an aqueous solution followed by stirring, preferably at a temperature above the glass transition temperature of the polymer. A dispersant aid may be added to facilitate the formation of small polymer particles and to prevent the particles from coagulating. Typical dispersant aids are surfactants. Both non-ionic and anionic surfactants are preferably used. According to a preferred embodiment of the present invention, no dispersant aids are necessary to obtain a stable aqueous dispersion of the polyester. In this case, the polyester is called self-dispersant. The self-dispersant property of the polyesters can be realized by introducing free acid groups, e.g., carboxylic acid groups in a protected form and/or sulpho groups in the polymer. These groups are introduced in the polymer by using suitable monomers. Preferably, sulpho groups are introduced by using sulpho derivatives of a dicarboxylic acid such as sulpho-terephthalic acid or sulpho-isophthalic acid as described in EP-A 0 078 559, EP-A 0 029 620 and EP-A 0 627 662. These EP-A documents describe polyesters, self-dispersant in an aqueous solution, and utilized in aqueous subbing layers on a polyester substrate for photographic materials. Preferably, the sulpho groups are introduced by using sulpho-isophthalic acid in combination with isophthalic aid and 2,6-naphthalenedicarboxylic acid. Preferably, sulpho-isophthalic acid accounts for between 5 and 20 mol percent, more preferably between 5 and 15 mol percent and most preferably between 7.5 and 12.5 mol percent with respect to the total acid moiety content of the polyester.

Ethylene glycol moieties are preferably used as the predominant diol moiety in the polyesters according to a preferred embodiment of the present invention.

By introducing a minor amount of monomer units containing three (or more) hydroxyl groups or carboxyl groups, to the majority of diol- and dibasic acid-monomers, a branching of the polymer can be introduced. Preferably, a monomer unit containing three (or more) hydroxyl groups is used in a preferred embodiment of the present invention. Most preferably, glycerol is used in combination with ethylene glycol. Preferably 0.25-10, more preferably 0.25-5.0, most preferably 0.5-3.0 mole percent of glycerol with respect to the total alcohol moiety content of the polyester is incorporated in the polyester according to a preferred embodiment of the present invention.

It has been discovered that printing plate precursors including a polyester with amounts of glycerol as described, may result in a further improvement of the clean-out behavior. A possible explanation for this result is the formation of shorter chain lengths in the polymer molecules due to the branching of the polymer. Due to these shorter chain lengths, entanglement is assumed to be less, resulting in a better clean out, i.e., a better removal of non-exposed areas.

The image-recording layer may further include a hydrophilic binder. Examples of suitable hydrophilic binders are homopolymers and copolymers of vinyl alcohol, (meth)acrylamide, methylol (meth)acrylamide, (meth)acrylic acid, hydroxyethyl (meth)acrylate, and maleic anhydride/vinylmethylether copolymers. Preferably, the hydrophilic binder includes polyvinylalcohol or polyacrylic acid.

The coating preferably also contains a compound which absorbs infrared light and converts the absorbed energy into heat. The amount of infrared absorbing agent in the coating is preferably between 0.25 and 25.0% by weight, more preferably between 0.5 and 20.0% by weight. In a preferred embodiment, its concentration is at least 6% by weight, more preferred at least 8% by weight. Preferred IR absorbing compounds are dyes such as cyanine, merocyanine, indoaniline, oxonol, pyrilium and squarilium dyes or pigments such as carbon black. Examples of suitable IR absorbers are described in, e.g., EP-A 823327, EP-A 978376, EP-A 1029667, EP-A 1053868, EP-A 1093934, WO 97/39894 and WO 00/29214.

Other preferred IR absorbers are described in EP 1 6145 41 and EP 1 736 312. These IR-dyes are especially preferred in the on-press development embodiment of the present invention, since these dyes give rise to a print-out image after exposure to IR-light, prior to development on press.

The infrared absorbing compound can be present in the image-recording layer and/or an optional other layer.

Addition of colorants such as dyes or pigments which provide a visible color to the coating and remain in the exposed areas of the coating after the processing step, are advantageous. Thus, the image-areas which are not removed during the processing step form a visible image on the printing plate and examination of the lithographic image on the developed printing plate becomes feasible. Typical examples of such contrast dyes are the amino-substituted tri- or diarylmethane dyes, e.g., crystal violet, methyl violet, victoria pure blue, flexoblau 630, basonylblau 640, auramine and malachite green. Also, the dyes which are discussed in depth in the detailed description of EP-A 400 706 are suitable contrast dyes. Dyes which, combined with specific additives, only slightly color the coating but which become intensively colored after exposure, as described in, for example, WO2006/005688 and are also of interest.

To protect the surface of the coating, in particular from mechanical damage, a protective layer may optionally be applied. The protective layer generally includes at least one water-soluble polymeric binder, such as polyvinyl alcohol, poly-vinylpyrrolidone, partially hydrolyzed polyvinyl acetates, gelatin, carbohydrates or hydroxyethylcellulose, and can be produced in any known manner such as from an aqueous solution or dispersion which may, if required, contain small amounts, i.e., less than 5% by weight, based on the total weight of the coating solvents for the protective layer, of organic solvents. The thickness of the protective layer can suitably be any amount, advantageously up to 5.0 μm, preferably from 0.05 to 3.0 μm, particularly preferably from 0.10 to 1.0 μm.

Besides the additional layers already discussed above, i.e., an optional light-absorbing layer including one or more compounds that are capable of converting infrared light into heat and/or a protective layer such as, e.g., a covering layer which is removed during processing, the coating may further contain other additional layer(s) such as, for example, an adhesion-improving layer between the image-recording layer and the support.

Optionally, the coating may further contain additional ingredients. These ingredients may be present in the image-recording layer or in an optional other layer. For example, additional binders, polymer particles such as matting agents and spacers, surfactants such as perfluoro-surfactants, silicon or titanium dioxide particles, development inhibitors, development accelerators colorants, metal complexing agents are well-known components of lithographic coatings. Preferred metal complexing agents are described in WO 2007/045515.

The support of the lithographic printing plate precursor has a hydrophilic surface or is provided with a hydrophilic layer. The support may be a sheet-like material such as a plate or it may be a cylindrical element such as a sleeve which can be slid around a print cylinder of a printing press.

In a preferred embodiment of the present invention, the support is a metal support such as aluminum or stainless steel. The support can also be a laminate including an aluminum foil and a plastic layer, e.g., polyester film. A particularly preferred lithographic support is an aluminum support. Any known and widely used aluminum materials can be used. The aluminum support has a thickness of about 0.1-0.6 mm. However, this thickness can be changed appropriately depending on the size of the printing plate used and the plate setters on which the printing plate precursors are exposed.

To optimize the lithographic properties, the aluminum support is subjected to several treatments well known in the art such as for example: degreasing, surface roughening, etching, anodization, sealing, surface treatment. In between such treatments, a neutralization treatment is often carried out. A detailed description of these treatments can be found in, e.g., EP-A 1 564 020 and EP-A 1 614 538.

A preferred aluminum substrate, characterized by an arithmetical mean center-line roughness Ra less then 0.45μ is described in EP 1 356 926.

An optimal ratio between pore diameter of the surface of the aluminum support and the average particle size of the hydrophobic thermoplastic particles may enhance the press run length of the plate and may improve the toning behavior of the prints. This ratio of the average pore diameter of the surface of the aluminum support to the average particle size of the thermo-plastic particles present in the image-recording layer of the coating, preferably ranges from 0.05:1 to 0.8:1, more preferably from 0.10:1 to 0.35:1.

According to another preferred embodiment, the support can also be a flexible support, which is provided with a hydrophilic layer. The flexible support is, e.g., paper, plastic film, thin aluminum or a laminate thereof. Preferred examples of plastic film are poly-ethylene terephthalate film, polyethylene naphthalate film, cellulose acetate film, polystyrene film, polycarbonate film, etc. The plastic film support may be opaque or transparent. Particular examples of suitable hydrophilic layers that may be supplied to a flexible support for use in accordance with a preferred embodiment of the present invention are disclosed in EP 601240, GB 1419512, FR 2300354, U.S. Pat. No. 3,971,660, U.S. Pat. No. 4,284,705, EP 1 614 538, EP 1 564 020 and U.S. 2006/0019196.

The printing plate precursor of a preferred embodiment of the present invention can be image-wise exposed directly with heat, e.g., by a thermal head, or indirectly by infrared light, preferably near infrared light. The infrared light is preferably converted into heat by an IR light absorbing compound as discussed above. The heat-sensitive lithographic printing plate precursor of a preferred embodiment of the present invention is preferably not sensitive to visible light. Most preferably, the coating is not sensitive to ambient daylight, i.e., visible (400-750 nm) and near UV light (300-400 nm) at an intensity and exposure time corresponding to normal working conditions so that the material can be handled without the need for a safe light environment.

The printing plate precursors of preferred embodiments of the present invention can be exposed to infrared light by, e.g., LEDs or an infrared laser. Preferably, the light used for the exposure is a laser emitting near infrared light having a wavelength in the range from about 700 to about 1500 nm, e.g., a semiconductor laser diode, a Nd:YAG or a Nd:YLF laser. Preferably, a laser emitting in the range between 780 and 830 nm is used. The required laser power depends on the sensitivity of the image-recording layer, the pixel dwell time of the laser beam, which is determined by the spot diameter (typical value of modern plate-setters at 1/e² of maximum intensity: 10-25 μm), the scan speed and the resolution of the exposure apparatus (i.e., the number of addressable pixels per unit of linear distance, often expressed in dots per inch or dpi; typical value: 1000-4000 dpi).

Two types of laser-exposure apparatuses are commonly used: internal (ITD) and external drum (XTD) plate-setters. ITD plate-setters for thermal plates are typically characterized by a very high scan speed up to 1500 m/sec and may require a laser power of several Watts. The Agfa Galileo T (trademark of Agfa Graphics NV) is a typical example of a plate-setter using the ITD-technology. XTD plate-setters for thermal plates having a typical laser power from about 20 mW to about 500 mW operate at a lower scan speed, e.g., from 0.1 to 20 m/sec. The Creo Trendsetter plate-setter family (trademark of Creo) and the Agfa Xcalibur plate-setter family (trademark of Agfa Graphics NV) both make use of the XTD-technology.

Due to the heat generated during the exposure step, the hydrophobic thermoplastic polymer particles fuse or coagulate so as to form a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic hydrophobic polymer particles, however, the temperature should be sufficiently below the decomposition temperature of the polymer particles. Preferably, the coagulation temperature is at least 10° C. below the temperature at which the decomposition of the polymer particles occurs. The coagulation temperature is preferably higher than 50° C., more preferably above 100° C.

In a preferred embodiment of the present invention, the printing plate precursor, after exposure, can be developed by a suitable processing liquid. In the development step, the non-exposed areas of the image-recording layer are substantially removed without essentially removing the exposed areas, i.e., without affecting the exposed areas to an extent that renders the ink-acceptance of the exposed areas unacceptable. The processing liquid can be applied to the plate, e.g., by rubbing it with an impregnated pad, by dipping, immersing, coating or spin-coating, spraying, pouring-on, either by hand or in an automatic processing apparatus. The treatment with a processing liquid may be combined with mechanical rubbing, e.g., by a rotating brush. The developed plate precursor can, if required, be post-treated with rinse water, a suitable correcting agent or preservative as known in the art. During the development step, any water-soluble protective layer present is preferably also removed. Suitable processing liquids are plain water or aqueous solutions.

In a preferred embodiment of the present invention, the processing liquid is a gum solution. A suitable gum solution which can be used in the development step is described in, for example, EP-A 1 342 568 and WO 2005/111727.

In another preferred embodiment of the present invention, the processing liquid is an alkaline solution. A suitable alkaline solution and method of developing is described in, for example, EP-A 1 614 539 and EP-A 1 614 540.

The development is preferably carried out at temperatures of from 20 to 40° C. in automated processing units as customary in the art. The development step may be followed by a rinsing step and/or a gumming step.

In another preferred embodiment of the present invention, the printing plate precursor can, after exposure, be mounted on a printing press and be developed on-press by supplying ink and/or fountain to the precursor or a single fluid ink.

The plate precursor can, if required, be post-treated with a suitable correcting agent or preservative as known in the art. To increase the resistance of the finished printing plate and hence to extend the run length, the layer can be heated to elevated temperatures (“baking”). During the baking step, the plate can be heated at a temperature which is higher than the glass transition temperature of the thermoplastic particles, e.g., between 100° C. and 230° C. for a period of 40 minutes to 5 minutes. A preferred baking temperature is above 60° C. For example, the exposed and developed plates can be baked at a temperature of 230° C. for 5 minutes, at a temperature of 150° C. for 10 minutes or at a temperature of 120° C. for 30 minutes. Baking can be done in conventional hot air ovens or by irradiation with lamps emitting in the infrared or ultraviolet spectrum. As a result of this baking step, the resistance of the printing plate to plate cleaners, correction agents and UV-curable printing inks increases.

The printing plate thus obtained can be used for conventional, so-called wet offset printing, in which ink and an aqueous dampening liquid is supplied to the plate. Another suitable printing method uses a so-called single-fluid ink without a dampening liquid. Suitable single-fluid inks have been described in U.S. Pat. No. 4,045,232; U.S. Pat. No. 4,981,517 and U.S. Pat. No. 6,140,392. In a preferred embodiment, the single-fluid ink includes an ink phase, also called the hydrophobic or oleophilic phase, and a polyol phase as described in WO 00/32705.

### EXAMPLES

### Preparation of the Polyester Polymers PE-1 to PE-6

The following abbreviations are used:

DCMN=2,6-di(carbo-methoxy)-naphthalene
DMSIP=dimethyl-sulpho-isophthalate sodium salt
DMIP=dimethyl-isophthalate
EG=ethyleneglycol
GLYC=glycerol
ZnAc₂=zinc acetate
Sb₂0₃=antimony(III)oxide
NaAc=sodium acetate dihydrate
TPhP=triphenylphosphate

The Tg (° C.) of the polyesters was measured by DSC (Differential Scanning Calorimetry).

### Synthesis of PE-1:

A reaction mixture of 488 g of DCMN (2 mole), 118.4 g of DMSIP (0.4 mole), 312 g of DMIP (1.6 moles), 480 g of EG (7.8 moles), 7.36 g of GLYC (0.08 mole), 263.5 mg of ZnAc₂, 116.6 mg of Sb₂0₃ and 656 mg of NaAc was gradually heated for 3 to 4 hours to 260° C. while stirring under a nitrogen atmosphere. Esterification took place and methanol/ethylene glycol was distilled off. 260 mg of TPhP was added as a stabilizer. The reaction mixture was then subjected to a reduced pressure of 1.2 mbar. Under these conditions, poly-condensation took place within 180 minutes. The polyester melt was allowed to settle on an aluminum foil and cooled to 25° C. A clear yellow and brittle solid was obtained. The solidified polyester was milled into a powder.

The Tg of the polyester is 68.7° C.

### Synthesis of PE-2 to PE-6:

PE-2 to PE-6 were synthesized according to the method described for PE-1.

The amount of the reactants (DCMN, DMSIP, DMIP, EG, GLYC, ZnAc₂, Sb₂0₃, NaAc and TPhP) and the reaction parameters (pressure and reaction time) used in the preparation of PE-1 to PE-6 and the Tg of the obtained polyester are shown in table 1.

TABLE 1
Reaction Parameters and Conditions Used
in the Preparation of PE-1 to PE-6

| | PE-1 | PE-2 | PE-3 | PE-4 | PE-5 | PE-6 |
|---|---|---|---|---|---|---|
| DCMN (g) | 488.0 | 488.0 | 488.0 | 488.0 | 488.0 | 683.2 |
| DMSIP (g) | 118.4 | 118.4 | 118.4 | 118.4 | 118.4 | 118.4 |
| DMIP (g) | 312.0 | 312.0 | 312.0 | 312.0 | 312.0 | 156.0 |
| EG (g) | 480.0 | 480.0 | 496.0 | 496.0 | 480.0 | 496.0 |
| GlYC (g) | 7.36 | 18.4 | — | — | 18.4 | — |
| ZnAc₂ (mg) | 263.5 | 315.2 | 175.5 | 351.2 | 263.5 | 175.5 |
| Sb₂0₃ (mg) | 116.6 | 233.2 | 233.2 | 233.2 | 116.6 | 233.2 |
| NaAc (mg) | 656.0 | 98.4 | 656.0 | 98.4 | 656.0 | 656.0 |
| TPhP (mg) | 260.0 | 520.0 | 260.8 | 520.0 | 260.0 | 260.8 |
| pressure | 1.2 | 0.6 | 1 | 0.96 | 0.5 | 0.8 |
| (mbar) | | | | | | |
| reaction time | 180 | 7 | 74 | 40 | 50 | 65 |
| (minutes) | | | | | | |
| Tg | 68.7 | 82.7 | 94 | 81.8 | 93.9 | 103.5 |

In Table 2, the monomer composition, used in the preparation of the Polyesters PE-1 to PE-6, is given in mole percent. The amount of the carboxyl (or ester) containing monomers is given relative to the total amount of carboxyl (or ester) containing monomers (sum of all carboxyl (or ester) containing monomers is 100%); the amount of the alcohols is given relative to the total amount of alcohols (sum of alcohols is 100%).

TABLE 2
Monomer Composition in Mole Percent of PE-1 to PE-6

| | PE-1 | PE-2 | PE-3 | PE-4 | PE-5 | PE-6 |
|---|---|---|---|---|---|---|
| DCMN | 50 | 50 | 50 | 50 | 50 | 70 |
| DMSIP | 10 | 10 | 10 | 10 | 10 | 10 |
| DMIP | 40 | 40 | 40 | 40 | 40 | 20 |
| EG | 99 | 97.5 | 100 | 100 | 97.5 | 100 |
| Glyc | 1 | 2.5 | — | — | 2.5 | — |
| Tg | 68.7 | 82.7 | 94 | 81.8 | 93.9 | 103.5 |

It is clear from table 2 that PE-6, containing most DCMN (2,6 dicarbomethoxynapthalene), is characterized by the highest Tg.

### Preparation of the Polyester Latex PE-LA-1 to PE-LA-5

In a two liter reactor, 846 ml of water and 200 g of a polyester (PE-1 to PE-5) were introduced. The mixture at room temperature was heated to 98° C. while stirring. After 4 hours at 98° C., the solution was cooled to 25° C. and 4 ml of a 5% biocide solution (5 wt % of 5-bromo-5-nitro-1,3-dioxane in a Ethanol/H₂O (70/30)) was added.

In Table 3, the average particle diameter (Ø) of the Polyester Latex PE-LA-1 to PE-LA-5 is shown. The average particle diameter is measured with a Brookhaven BI-90 particle sizer.

TABLE 3
Average Particle Diameter of PE-LA-1 to PE-LA-5

| Polyester Latex (PE- | Polyester | |
|---|---|---|
| LA) | (PE) | Ø (nm) |
| PE-LA-1 | PE-1 | 18 |
| PE-LA-2 | PE-2 | 20 |
| PE-LA-3 | PE-3 | 28 |
| PE-LA-4 | PE-4 | 23 |
| PE-LA-5 | PE-5 | 16 |

### Preparation of the Lithographic Substrate

A 0.30 mm thick aluminum foil was degreased by immersing the foil in an aqueous solution containing 40 g/l of sodium hydroxide at 60° C. for 8 seconds and rinsed with demineralized water for 2 seconds. The foil was then electrochemically grained during 15 seconds using an alternating current in an aqueous solution containing 12 g/l of hydrochloric acid and 38 g/l of aluminum sulfate (18-hydrate) at a temperature of 33° C. and a current density of 274 A/dm². After rinsing with demineralized water for 2 seconds, the aluminum foil was then desmutted by etching with an aqueous solution containing 155 g/l of sulfuric acid at 70° C. for 4 seconds and rinsed with demineralized water at 25° C. for 2 seconds. The foil was subsequently subjected to anodic oxidation during 13 seconds in an aqueous solution containing 155 g/l of sulfuric acid at a temperature of 45° C. and a current density of 23.5 A/dm², then washed with demineralized water for 2 seconds and post-treated for 10 seconds with a solution containing 4 g/l of polyvinylphosphonic acid at 40° C., rinsed with demineralized water at 20° C. during 2 seconds and dried.

The support thus obtained has a surface roughness Ra of 0.51 μm and an anodic weight of 4 g/m² of Al₂O₃.

### Example 1

### Preparation of the Printing Plate Precursors PPP-1 to PPP-5

The printing plate precursors 1-5 were produced by applying a coating onto the above described lithographic substrate. The composition of the coating is defined in Table 4. The average particle diameters of the hydrophobic thermoplastic particles are indicated in Table 5. The coating was applied from an aqueous coating solution and a dry coating weight of 0.8 g/m² was obtained.

TABLE 4
Composition of the Dry Coating (weight percent, wt %)

| | PPP-1 | PPP-2 | PPP-3 | PPP-4 | PPP-5 |
|---|---|---|---|---|---|
| INGREDIENTS (% wt) | (Comp.) | (Inv.) | (Inv.) | (Inv.) | (Inv.) |
| Sty/AN copolymer (1) | 73 | | | | |
| PE-LA-1 | | 75 | 72 | — | — |
| PE-LA-2 | | — | — | 75 | 72 |
| IR-1 (2) | 12 | 10 | = | = | = |
| Polyacrylic acid binder (3) | 15 | | | | |
| Polyvinylacohol binder (4) | | 15 | 18 | 15 | 18 |

(1) An aqueous dispersion of a copolymer of styrene and
acrylonitrile, weight ratio 60/40, stabilized with an
anionic wetting agent; average particle size of 36 nm
(2) Infrared absorbing dye IR-1 with the following structure:

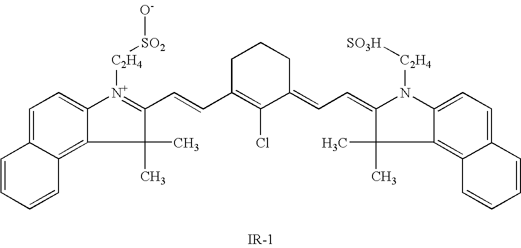

(3) Glascol D15 from allied Colloids, Mw = 2.7 × 10⁷ g/mol
(4) Polyvinylalcohol, Aqueous solution of Erkol WX48/20,
commercially available from Erkol, part of Acetex.

### Imaging and Print Results of the Plate Precursors PPP-1 to PPP-5

The printing plate precursors PPP-1 to PPP-5 were exposed with a Creo Trendsetter 2344T (40W) (plate-setter, trademark from Creo, Burnaby, Canada), operating at 150 rpm and varying energy densities up to 330 mJ/cm².

The plate precursors thus obtained were mounted on a GTO46 printing press (available from Heidelberger Druckmaschinen AG), and a print job was started using K+E Novavit 800 Skinnex ink (trademark of BASF Drucksysteme GmbH) and 3% Rotamatic in 10% isopropanol as a fountain liquid.

The lithographic properties of the plates were evaluated by the sensitivity (energy at which 2% dots are clearly visible on the prints) and a visual inspection of the appearance of toning in the non-image areas of the plates. These lithographic properties are shown in Table 5, together with the average particle size (Ø(nm)) and the amount relative to the total weight of all ingredients in the image recording layer (wt % Latex) of the thermoplastic hydrophobic particles used in the printing plate precursors.

TABLE 5
Lithographic Properties PPP-1 to PPP-5

| | | | | Sensitivity |
|---|---|---|---|---|
| | Ø (nm) | wt % Latex | Toning behavior | (mJ/cm²) |
| PPP-1 | 36 | 73 | severe toning | Not relevant |
| (comp) | | | | due to toning |
| PPP-2 | 18 | 75 | slight toning | 270 |
| (Inv) | | | tendency | |
| PPP-3 | 18 | 72 | no toning | 290 |
| (Inv) | | | | |
| PPP-4 | 20 | 75 | slight toning | 265 |
| (Inv) | | | tendency | |
| PPP-5 | 20 | 72 | no toning | 290 |
| (Inv) | | | | |

The results shown in Table 5 clearly demonstrate that the comparative printing plate precursor (PPP-1) including hydrophobic thermoplastic particles, consisting of a styrene/acrylonitrile copolymer, with an average particle diameter of 36 nm, shows severe toning in the non-printing areas (i.e., bad clean out). The printing plate precursors according to preferred embodiments of the present invention (PPP-2 to PPP-5) shows no, or slight, toning. This clearly demonstrates that a printing plate precursor including hydrophobic thermoplastic particles including a polyester, with an average particle size of 18 or 20 nm, has a good image quality and a good lithographic performance.

The results indicate also, for the printing plate precursors according to preferred embodiments of the present invention, a further improvement of the clean-out behavior (i.e., less toning) when the polyester latex concentration is less then 75 percent by weight relative to the weight of all ingredients of the coating (PPP-3 and PPP-5).

### Example 2

### Preparation of the Printing Plate Precursors PPP-6 and PPP-7

The printing plate precursors PPP-6 and PPP-7 were produced by applying a coating onto the above described lithographic substrate. The composition of the coating is defined in Table 6. The coating was applied from an aqueous coating solution and a dry coating weight of 0.8 g/m² was obtained.

TABLE 6
Composition of the Dry Coating (weight percent, % wt)

| | | | Binder |
|---|---|---|---|
| | PE-LA-1 | IR-1 | (1) |
| PPP-6 (Inv.) | 75% | 10% | 15% |
| PPP-7 (Inv.) | 72% | 10% | 18% |

(1) Glascol D15 from allied Colloids, Mw = 2.7 × 10⁷ g/mol

### Imaging and Print Results of Plate Precursors PPP-6 and PPP-7

The printing plate precursors PPP-6 and PPP-7 were exposed with a Creo Trendsetter 2344T (40W) (plate-setter, trademark from Creo, Burnaby, Canada), operating at 150 rpm and varying energy densities up to 350 mJ/cm².

The plate precursors thus obtained were mounted on a GTO46 printing press (available from Heidelberger Druckmaschinen AG), and a print job was started using K+E Novavit 800 Skinnex ink (trademark of BASF Drucksysteme GmbH) and 3% Rotamatic in 10% isopropanol as a fountain liquid.

The lithographic properties of the plates were evaluated by the following criteria:

Sensitivity: energy at which 2% dot is clearly reproduced on print

Ink acceptance: OK when ≦25 pages to be printed before good ink acceptance

Shelf-life: OK when no toning and ink-build-up on blanket after the printing plate precursor has been aged for 7 days at 35° C./80% relative humidity.

The lithographic properties of PPP-6 and PPP-7 are shown in Table 7.

TABLE 7
Lithographic Properties PPP-6 and PPP-7

| | | | Shelf-life | |
|---|---|---|---|---|
| | | | | Ink-build- |
| | Sensitivity | Ink- | Toning | up on |
| | mJ/cm² | acceptance | behavior | blanket |
| PPP-6 (Inv.) | 300 | OK | OK | Yes |
| PPP-7 (Inv.) | 300 | OK | OK | No |

The results indicate, for the printing plate precursors according to preferred embodiments of the present invention, an improvement of the shelf life when the polyester latex concentration is less then 75 percent by weight relative to the weight of all ingredients of the coating

### Example 3

### Preparation of the Printing Plate Precursor PPP-8, PPP-9 and PPP-10

The printing plate precursors PPP-8 to PPP-10 were produced by applying a coating solution onto the above described lithographic substrate. The composition of the coating is defined in Table 8. The coating was applied from an aqueous coating solution and a dry coating weight of 0.8 g/m² was obtained.

TABLE 8
Composition of the Dry Coating (weight percent, % wt)

| | PPP-8 | PPP-9 | PPP-10 |
|---|---|---|---|
| INGREDIENTS | (Inv.) | (Inv.) | (Inv.) |
| PE-LA-1 | 72 | — | — |
| PE-LA-2 | — | 72 | — |
| PE-LA-3 | — | — | 72 |
| IR-1 | 10 | 10 | 10 |
| Polyacrylic acid | 18 | 18 | 18 |
| binder (1) | | | |

(1) Glascol D15 from allied Colloids, Mw = 2.7 × 10⁷ g/mol

### Imaging and Print Results of the Plate Precursor PPP-8 to PPP-10

The imaging and print results of the printing plate precursors PPP-8 to PPP-10 are evaluated as described in Example 2. The results are shown Table 9.

TABLE 9
Lithographic Properties PPP-8 to PPP-10

| | | | Shelf-life | |
|---|---|---|---|---|
| | | | | ink-build- |
| | Sensitivity | Ink- | toning | up on |
| | mJ/cm² | acceptance | behavior | blanket |
| PPP-8 (Inv.) | 300 | OK | OK | No |
| PPP-9 (Inv.) | 300 | OK | OK | No |
| PPP-10 (Inv.) | 350 | OK | OK | Yes |

The results in Table 9 demonstrate that printing plate precursors including hydrophobic thermoplastic particles including a polyester, wherein glycerol as monomer is incorporated (PPP-8 and PPP-9), are characterized by an improved shelf life.

### Example 4

### Preparation of the Printing Plate Precursor PPP-11 to PPP-14

Printing plate precursors PPP-11 to PPP-14 were produced by applying a coating solution onto the above described lithographic substrate. The composition of the coating is defined in Table 10. The coating was applied from an aqueous coating solution and a dry coating weight of 0.8 g/m² was obtained.

TABLE 10
Composition of Dry Coating (weight percent, % wt)

| | PPP-11 | PPP-12 | PPP-13 | PPP-14 |
|---|---|---|---|---|
| INGREDIENTS | (Inv.) | (Comp.) | (Inv.) | (Inv.) |
| PE-LA-4 | 72 | — | — | — |
| PE-LA-5 | — | 72 | — | — |
| PE-LA-1 | — | — | 72 | — |
| PE-LA-2 | — | — | — | 72 |
| IR-1 | 10 | 10 | 10 | 10 |
| Polyacrylic acid | 18 | 18 | 18 | 18 |
| binder (1) | | | | |

(1) Glascol D15 from allied Colloids, Mw = 2.7 × 10⁷ g/mol

### Imaging and Print Results of Plate Precursors PPP-11 to PPP-14

The imaging and print results of the printing plate precursors PPP-11 to PPP-14 are evaluated as described in Example 2. The lithographic properties are shown in Table 11, together with the average particle diameter (Ø) of the hydrophobic thermoplastic particles present in the printing plate precursors.

TABLE 11
Lithographic Properties of PPP-11 to PPP-15

| | | | | Shelf life | |
|---|---|---|---|---|---|
| | | | | | Ink-build- |
| | | Sensitivity | Ink- | Toning | up on |
| | Ø (nm) | mJ/cm² | acceptance | behavior | blanket |
| PPP-11 | 23 | 350 | OK | OK | Yes |
| (Inv.) | | | | | |
| PPP-12 | 16 | 350 | Not OK | OK | Yes |
| (Comp.) | | | | | |
| PPP-13 | 18 | 300 | OK | OK | No |
| (Inv.) | | | | | |
| PPP-14 | 20 | 300 | OK | OK | No |
| (Inv.) | | | | | |

The results of Table 12 demonstrate that a printing plate precursor including a polyester-latex with an average particle size of 16 nm (PPP-12) shows a bad ink-acceptance and show ink-built-up on the blanket after ageing.

The printing plate precursors, including a polyester latex with a particle size of 18 nm or higher, have a good ink-acceptance. PPP-11 including hydrophobic thermoplastic particles including a polyester, wherein no glycerol as monomer is incorporated in small amounts, has a worse shelf life compared to PPP-13 and PPP-14 including hydrophobic thermoplastic particles including a polyester, wherein a small amount of glycerol as monomer is incorporated.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-10. (canceled)

11. A heat-sensitive negative-working lithographic printing plate precursor comprising:
a support having a hydrophilic surface or which is provided with a hydrophilic layer; and
a coating provided on the support, the coating including an image-recording layer which includes hydrophobic thermoplastic polymer particles; wherein
the hydrophobic thermoplastic polymer particles include a polyester and have an average particle diameter from 18 nm to 50 nm.

12. A heat-sensitive negative-working lithographic printing plate precursor according to claim 11, wherein the hydrophobic thermoplastic particles have an average particle size from 18 nm to 30 nm.

13. A heat-sensitive negative-working lithographic printing plate precursor according to claim 11, wherein the hydrophobic thermoplastic particles are self-dispersant in water.

14. A heat-sensitive negative-working lithographic printing plate precursor according to claim 11, wherein the polyester includes between 5-20 mole percent of a sulpho-substituted dicarboxylic acid with respect to the total acid moiety content of the polyester.

15. A heat-sensitive negative-working lithographic printing plate precursor according to claim 11, wherein the polyester includes at least 25 mole percent of a naphthalene-dicarboxylic acid with respect to the total acid moiety content of the polyester.

16. A heat-sensitive negative-working lithographic printing plate precursor according to claim 14, wherein the polyester includes at least 25 mole percent of a naphthalene-dicarboxylic acid with respect to the total acid moiety content of the polyester.

17. A heat-sensitive negative-working lithographic printing plate precursor according to claim 11, wherein the polyester includes 0.25-10 mole percent of glycerol with respect to the total alcohol moiety content of the polyester.

18. A heat-sensitive negative-working lithographic printing plate precursor according to claim 14, wherein the polyester includes 0.25-10 mole percent of glycerol with respect to the total alcohol moiety content of the polyester.

19. A heat-sensitive negative-working lithographic printing plate precursor according to claim 15, wherein the polyester includes 0.25-10 mole percent of glycerol with respect to the total alcohol moiety content of the polyester.

20. A heat-sensitive negative-working lithographic printing plate precursor according to claim 16, wherein the polyester includes 0.25-10 mole percent of glycerol with respect to the total alcohol moiety content of the polyester.

21. A heat-sensitive negative-working lithographic printing plate precursor according to claim 11, wherein the amount of the polyester particles relative to the total amount of ingredients of the image-recording layer is between 20 and 90 percent by weight.

22. A heat-sensitive negative-working lithographic printing plate precursor according to claim 14, wherein the amount of the polyester particles relative to the total amount of ingredients of the image-recording layer is between 20 and 90 percent by weight.

23. A heat-sensitive negative-working lithographic printing plate precursor according to claim 16, wherein the amount of the polyester particles relative to the total amount of ingredients of the image-recording layer is between 20 and 90 percent by weight.

24. A heat-sensitive negative-working lithographic printing plate precursor according to claim 20, wherein the amount of the polyester particles relative to the total amount of ingredients of the image-recording layer is between 20 and 90 percent by weight.

25. A method for making a lithographic printing plate comprising the steps of:
providing a printing plate precursor according claim 11;
exposing the printing plate precursor to heat or IR-light; and
developing the exposed precursor by removing the unexposed areas in a processing liquid.

26. A method for making a lithographic printing plate comprising the steps of:
providing a printing plate precursor according claim 14;
exposing the printing plate precursor to heat or IR-light; and
developing the exposed precursor by removing the unexposed areas in a processing liquid.

27. A method for making a lithographic printing plate comprising the steps of:
providing a printing plate precursor according to claim 11;
exposing the printing plate precursor to heat or IR-light;
mounting the exposed printing plate precursor on a printing press; and
developing the printing plate precursor by removing the unexposed areas by supplying ink and/or fountain solution to the precursor.

28. A method for making a lithographic printing plate comprising the steps of:
providing a printing plate precursor according to claim 14;
exposing the printing plate precursor to heat or IR-light;
mounting the exposed printing plate precursor on a printing press; and
developing the printing plate precursor by removing the unexposed areas by supplying ink and/or fountain solution to the precursor.

29. A method of lithographic printing comprising the steps of:
supplying ink and fountain solution to a printing plate obtained by the method of claim 25 on a printing press; and
transferring the ink to paper.

30. A method of lithographic printing comprising the steps of:
supplying ink and fountain solution to a printing plate obtained by the method of claim 26 on a printing press; and
transferring the ink to paper.

31. A method of lithographic printing comprising the steps of:
supplying ink and fountain solution to a printing plate obtained by the method of claim 27 on a printing press; and
transferring the ink to paper.

32. A method of lithographic printing comprising the steps of:
supplying ink and fountain solution to a printing plate obtained by the method of claim 28 on a printing press; and
transferring the ink to paper.
